(19) United States
(12) Patent Application Publication
(10) Pub. No.: US 2004/0233075 A1
(43) Pub. Date: Nov. 25, 2004

(54) 8B/10B encoder/decoder including logic gates

(76) Inventors: Chang Won Park, Suwon-si (KR); Sung Ju Park, Ansan-si (KR); Tae Sik Kim, Seoul (KR); Hyung Soo Lee, Seoul (KR); Ki Man Cheon, Pyeongtaek-si (KR)

Correspondence Address: STANZIONE & KIM, LLP, 1740 N STREET, N.W., FIRST FLOOR, WASHINGTON, DC, 20036, US

(21) Appl. No.: 10/745,656

(22) Filed: Dec. 29, 2003

(30) Foreign Application Priority Data
May 22, 2003 (KR) 10-2003-32485

(51) Int. Cl. H03M 7/00

(52) U.S. Cl. 341/59

(57) ABSTRACT

An 8B/10B encoder/decoder including logic gates. The 8B/10B encoder including logic gates including a 5B/6B encoding block to compute 6 bit output data, in which the number of ‘0’s and the number of ‘1’s are balanced, from 5 bit input data; a 3B/4B encoding block to compute 4 bit output data, in which the number of ‘0’s and the number of ‘1’s are balanced, from 3 bit input data; and a disparity computation block to create and output a disparity in response to outputs and clocks of the 5B/6B encoding block and the 3B/4B encoding block. Thus, an 8B/10B encoder/decoder including logic gates uses a two-group logic combination method with emphasis on speed rather than size. The minimum number of stages for data processing at logic gate level guarantees more stable and fast operation.

### CROSS-REFERENCE TO RELATED APPLICATIONS

This application claims the benefit of Korean Patent Application No. 10-2003-32485 filed with the Korea Industrial Property Office on May 22, 2003, the disclosure of which is incorporated herein by reference.

### BACKGROUND OF THE INVENTION

1. Field of the Invention

The present invention relates to an 8B/10B encoder/decoder including logic gates and, more particularly, to an 8B/10B encoder/decoder which guarantees a high speed operation by minimizing steps of data processing employing a two-group logic combination method in a logic gate structure.

2. Background of the Related Art

In the present, many internet services are developed by a number of service providers according to construction of broadband networks, improvements in network speed and bandwidth, and wide spread of the internet.

If a netizen only has a computer system which is connected to a network, the netizen can be provided with many internet application services. Currently, contents and types of the internet services are changing from simple data such as texts, images, and file transfers to broadband multimedia data such as audio and video streams. In order to provide these services, it is required to enhance data processing speed, increase storage capacity in an internet server system, and enhance transmission speed of a network.

U.S. Pat. No. 4,486,739, Franaszek et al., discloses a conventional art of an 8B/10B encoder/decoder which consists of logic gates. When the art was suggested, circuit size was more important than processing speed. Hence, a configuration of the logic gate in the conventional 8B/10B encoder/decoder was designed by putting emphasis on size rather than speed.

In addition, a data processing is performed through several stages of logic gates to reduce the circuit size in the conventional 8B/10B encoder/decoder. So, there remains a problem that clock timing becomes slow.

Korean Published Patent No. 10-2001-0063785, Do et al., discloses an 8B/10B encoder/decoder constructed by adopting a pipe-lining method to provide an operating clock speed over 125 MHz. The use of the pipe-lining method guarantees a stable and fast operation without a timing violation in implementation of a circuit.

Since the 8B/10B encoder/decoder employing the pipe-lining method must perform buffering between proper gate logics for high speed operations, a step for the buffering is additionally required.

FIG. 1 is a schematic diagram of a logic gate of a 5B/6B encoding block in a conventional 8B/10B encoder. Five (5) bits (EDCBA) 120 among 8 input bits (HGF EDCBA) and a control signal K 100 is inputted. Then, 6 bits (abcdei) 130 among 10 output bits (abcdei fghj), S 110 for processing of an exception in 3B/4B encoding, and a signal for disparity computation are outputted. The output according to the disparity value is determined by COMPLS6 160 transferred from a disparity computation block. PDOS6, PD_{—}1S6, NDOS6, and ND_{—}1S6 which are computed in encoding process are transferred to the disparity computation block for disparity computation. Then, PDL6 is transferred again from the disparity computation block for determination of S.

FIG. 2 is a schematic diagram of a logic gate of a disparity computation block in a conventional 8B/10B encoder. With data exchanged between a 5B/6B encoding block and a 3B/4B encoding block, COMPLS6 160 and COMPLS4 170 which determine whether to make a final output signal complemented according to the disparity value are transferred to the corresponding blocks. The process of solving S, the critical path process among 5B/6B encoding process, is achieved through 14 stages of logic gates.

FIG. 3 is a schematic diagram of a logic gate of a 3B/4B encoding block in a conventional 8B/10B encoder. Three (3) bits (HGF) 140 among 8 input bits (HGF EDCBA), control signal K 100, and S 110 which is transferred from the 5B/6B block are inputted. Then, 4 bits (fghj) 150 among 10 output bits (abcdei fghj) are outputted. The process of solving j, the critical path process among 3B/4B encoding process, is achieved through 6 stages of logic gates.

FIG. 4 is a schematic diagram of a logic gate of the critical path in a conventional 8B/10B encoder. The 8B/10B decoder restores received 10 bit data to original 8 bit data and control signal K. The process of solving C, the critical path process among 8B/10B decoding process, is achieved through 10 stages of logic gates.

Data processing at low speed is feasible in such an encoder/decoder. However, data processing at high speed shows limitation due to a clock timing.

### SUMMARY OF THE INVENTION

Accordingly, it is an aspect of the present invention to provide an 8B/10B encoder/decoder using a two-group logic combination method in order to minimize the steps of data processing.

Additional aspects and/or advantages of the invention will be set forth in part in the description which follows and, in part, will be obvious from the description, or may be learned by practice of the invention.

The foregoing and/or other aspects of the present invention are achieved by providing an 8B/10B encoder including logic gates comprising: a 5B/6B encoding block to compute 6 bit output data, in which the number of ‘0’s and the number of ‘1’s are balanced, from 5 bit input data; a 3B/4B encoding block to compute 4 bit output data, in which the number of ‘0’s and the number of ‘1’s are balanced, from 3 bit input data; and a disparity computation block to create and output a disparity in response to outputs and clocks of the 5B/6B encoding block and the 3B/4B encoding block.

The foregoing and/or other aspects of the present invention are achieved by providing an 8B/10B decoder including logic gates comprising: a 5B/6B decoding block for computing to compute 5 bit output data from 6 bit input data in which the number of ‘0’s and the number of ‘1’s are balanced; a 3B/4B decoding block for computing to compute 3 bit output data from 4 bit input data in which the number of ‘0’s and the number of ‘1’s are balanced; and a disparity computation block for creating and outputting to create and output a disparity in response to outputs and clocks of the 5B/6B decoding block and the 3B/4B decoding block.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIG. 1 is a schematic diagram of a logic gate of a 5B/6B encoding block in a conventional 8B/10B encoder.

FIG. 2 is a schematic diagram of a logic gate of a disparity computation block in a conventional 8B/10B encoder.

FIG. 3 is a schematic diagram of a logic gate of a 3B/4B encoding block in a conventional 8B/10B encoder.

FIG. 4 is a schematic diagram of a logic gate of the critical path in a conventional 8B/10B encoder.

FIG. 5 is a schematic diagram of a logic gate of a 5B/6B encoding block in an 8B/10B encoder according to the present invention.

FIG. 6 is a schematic diagram of a logic gate of a disparity computation block in an 8B/10B encoder according to the present invention.

FIG. 7 is a schematic diagram of a logic gate of a 3B/4B encoding block in an 8B/10B encoder according to the present invention.

FIG. 8 is a schematic diagram of a logic gate of the critical path process in an 8B/10B decoder according to the present invention.

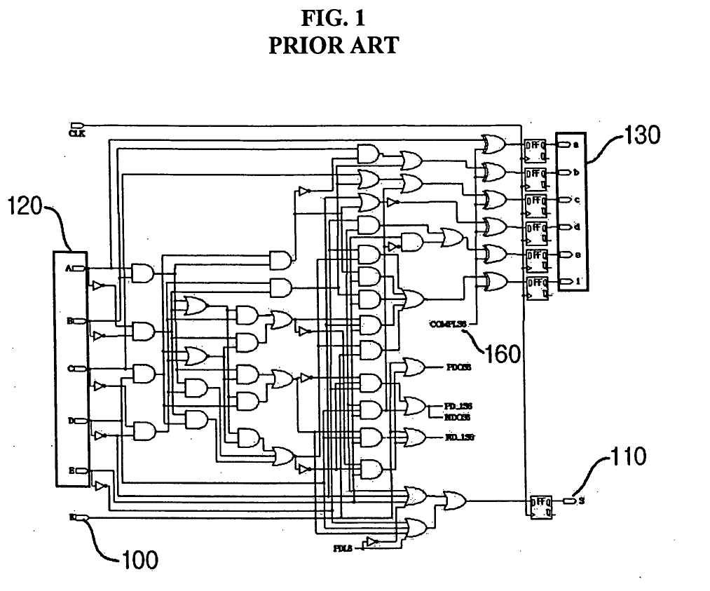

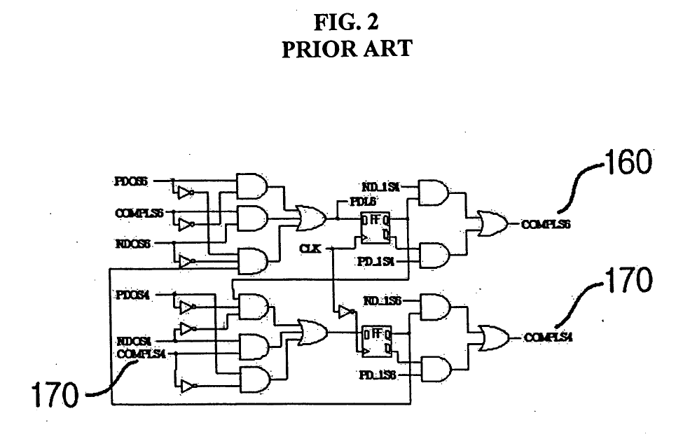

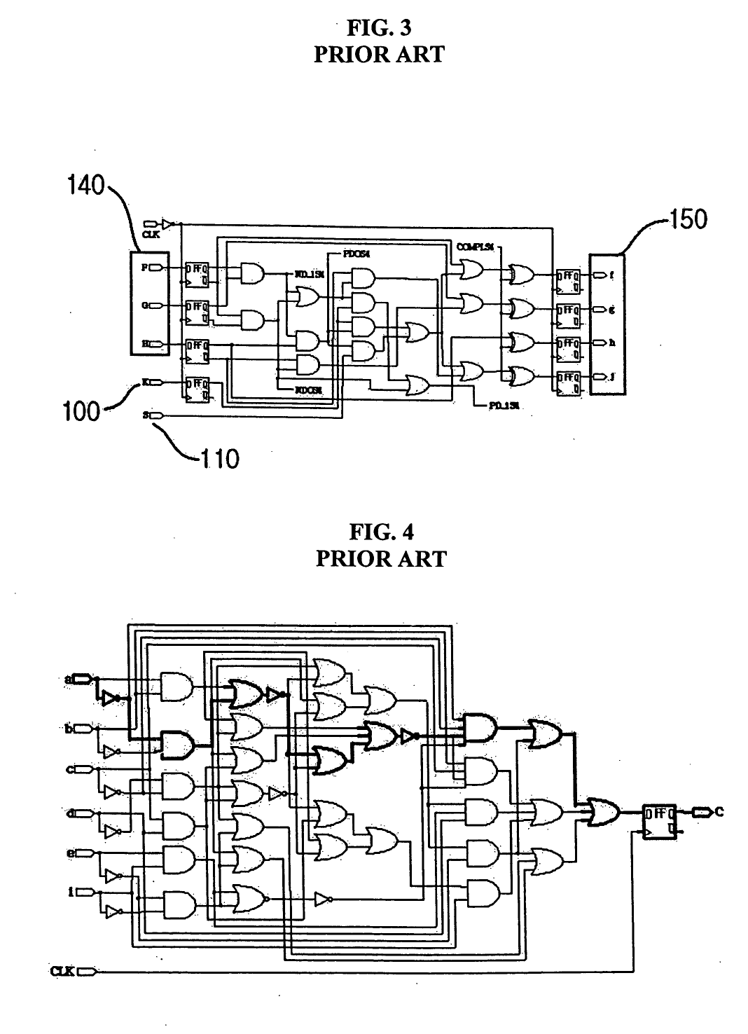

### DETAILED DESCRIPTION OF THE PREFERRED EMBODIMENTS

The present invention is directed to an 8B/10B encoder/decoder including logic gates that substantially obviates one or more problems due to limitations and disadvantages of the related art.

An object of the present invention is to provide an 8B/10B encoder/decoder using a two-group logic combination method in order to minimize the steps of data processing.

To achieve the object, the present invention provides an 8B/10B encoder including logic gates comprising: a 5B/6B encoding block for computing 6 bit output data, in which the number of ‘0’s and the number of ‘1’s are balanced, from 5 bit input data; a 3B/4B encoding block for computing 4 bit output data, in which the number of ‘0’s and the number of ‘1’s are balanced, from 3 bit input data; and a disparity computation block for creating and outputting a disparity in response to outputs and clocks of the 5B/6B encoding block and the 3B/4B encoding block.

The present invention also provides an 8B/10B decoder including logic gates comprising: a 5B/6B decoding block for computing 5 bit output data from 6 bit input data in which the number of ‘0’s and the number of ‘1’s are balanced; a 3B/4B decoding block for computing 3 bit output data from 4 bit input data in which the number of ‘0’s and the number of ‘1’s are balanced; and a disparity computation block for creating and outputting a disparity in response to outputs and clocks of the 5B/6B decoding block and the 3B/4B decoding block.

References will now be made in detail to the preferred embodiments of the present invention, examples of which are illustrated in the accompanying drawings.

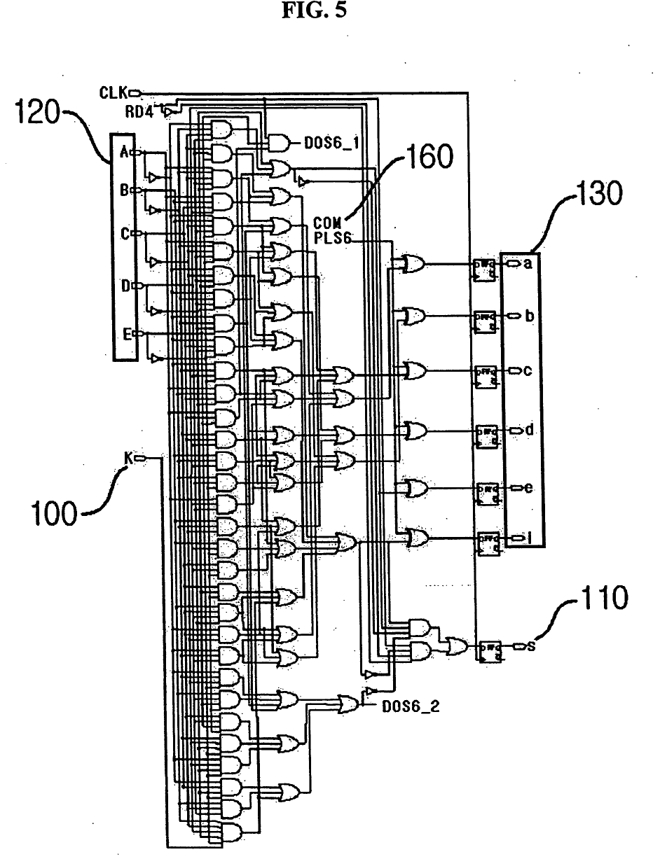

FIG. 5 is a schematic diagram of a logic gate of a 5B/6B encoding block in an 8B/10B encoder according to the present invention. Five (5) bits (EDCBA) 120 among 8 input bits (HGF EDCBA), and control signal K 100 are inputted. Then, 6 bits 130 among 10 output bits (abcdei fghj), S 110 for processing of an exception in 3B/4B encoding and a signal for disparity computation 160 are outputted. In the computation of 6 bit output from 5 bit input, 6 bit encoding result for negative(−) disparity and an exceptional situation when input is ABCDE, K is 1, and i=1 can be expressed as following two-group logic equations,

a=AB′C′D′E+A′BC′D′E′+A′B′D′E′+ABCD′+ACE+AC′D+A′B′C′D+AB′C+ABC′

b=AB′C′D′E′+A′C′D′E+A′CD′E+ABCD′+A′BD+BDE′+A′BC+A′B′C′D+ABC′

c=A′BC′D′E′+AB′C′D′E′+A′B′D′E+A′B′DE′+ABCD′+ACE+B′CD+A′BC+AB′C

d=A′BC′D′E′+AB′C′D′E′+A′B′D′E′+B′CD+A′BD+BDE′+AC′D

e=A′B′C′D′+ABCD+E

i=C′D′E′+AB′C′D′E+ABCD+A′C′D′E+A′B′D′E+A′CD′E′+A′B′DE′+A′C′E′+B′C′E′B′D′E′+A′B′C′D+ABCDEK.

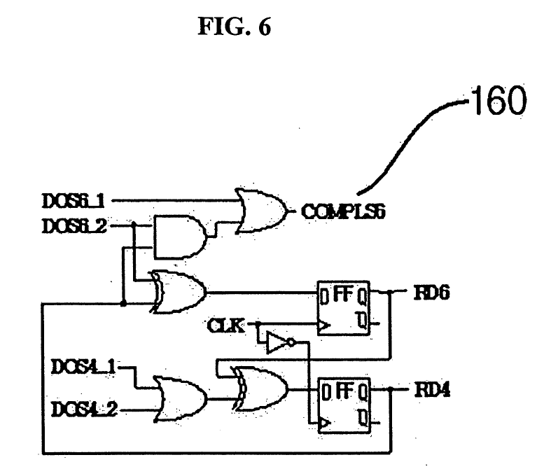

FIG. 6 is a schematic diagram of a logic gate of a disparity computation block in an 8B/10B encoder according to the present invention. With data exchanged between a 5B/6B encoding block and a 3B/4B encoding block, when the final output is computed in FIG. 5, the output is determined as referenced to COMPLS6 160 which determines whether to make an output signal complemented. Logical condition that the value of COMPLS6 becomes ‘1’ and hence the output signal gets complemented is (1) when present disparity is positive and next disparity is negative; and, (2) for the exceptional situation, when 5 input bits are ABCD′E′ and present disparity is positive. As an encoder composed of several logic gates does not guarantee high speed data processing, the 5B/6B encoding block is designed by using the two-group logic combination. The process of solving S, the critical path process among 5B/6B encoding process, is achieved through 7 stages of logic gates, which are 7 stages less than the conventional 5B/6B encoding block.

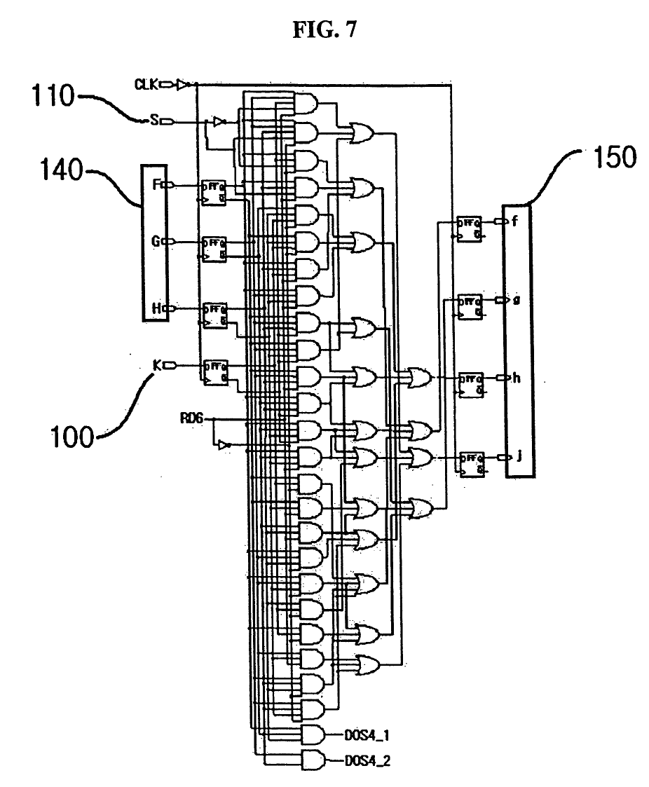

FIG. 7 is a schematic diagram of a logic gate of a 3B/4B encoding block in an 8B/10B encoder according to the present invention. Three (3) bits (HGF) 140 among 8 input bits (HGF EDCBA), control signal K 100, and S 110 which is transferred from the 5B/6B block are inputted. Then, 4 bits (fghj) 150 among 10 output bits (abcdei fghj) are outputted. When 4 bit output is computed from 3 bit input, present disparity, the control signal K, and S for processing of an exception are used as input since basic input number is less than for the 5B/6B encoding block. That is, the step of solving the final result is much simplified by using every possible conditions as input. The two-group logic equation is as follows (R is a present disparity);

f=FK′S′R+FHSR+FHKR+FG′HK′+FG′HK′+FG′H′K′+FG′H′R+F′KT+FGH′R′+F′G′HR′+F′G′H′R′

g=F′GHK′+F′GH′K′+F′GHR+F′H′R+FGHR′+FGH′R′+FKR′+F′G′HR′

h=G′H′KR′+F′H′KR′+FGH′R+F′GHK′+F′GHR+FG′HK′+G′HR+FGHR′+F′G′H′R′

j=FGK′S′R+FGHSR′+F′GH′K′+FG′H′K′+FG′H′R+HKR′+G′H′R+F′G′HR′+F′G′H′R.

When the 5B/6B encoding block is designed by using the two-group logic combination, the process of solving j, a critical path process among 3B/4B encoding process, is achieved through 4 stages of logic gates, which are 2 stages less than the conventional 3B/4B encoding block. The original 8 data bits (HGF EDCBA) and the control signal K are outputted by receiving 8B/10B data (abcdei fghj) as input according to the present invention. The decoding logic equations for computing the 8 bit output and the control signal K from 10 input bits are as follows;

K=egh′j′+e′ghj+cdei+c′d′e′i′

H=c′d′e′ih′j+(c′d′e′i′)′hj′+g′h′j′+ghj+f′g′h′+fgj

G=c′d′e′i′g′j′+c′d′e′i′g′h′+(c′d′e′i′)′fj+(c′d′e′i′)′gh+fh′j′+f′hj

F=c′d′e′i′g′+(c′d′e′i′)′fj′+(c′d′e′i′)′g′h′+fgj′+f′hj

E=ab′c′di′+a′c′d′ei+b′c′d′ei+a′b′cdi′+bdei′+a′c′e′i′+b′cei+abe+bce+c′d′e′i′+ace+a′b′d′e′+a′c′d′e′+a′b′c′e′+b′c′d′e′

D=ab′c′de′i+a′b′cdi′+a′b′cdi+abei+bc′de′i′+abci+ab′ce′i+a′bc′d+acei+dei′+c′d′e′i′+bcdi′+a′b′d′e′+a′c′d′e′+b′c′d′e′

C=a′bcd′e′i+a′b′cdi+abdi+acd′e′i′+a′c′dei+ab′ce′i+a′c′e′i′+ab′cd′+b′cei+cei′+c′d′e′i+bcdi′+a′c′d′e′+a′b′c′e′+b′c′d′e′.

B=a′bcd′e′i+abc′d′e′i+a′c′d′ei+acdi+bc′de′i+acd′e′i+a′c′dei+a′bc′d+acei+bei′+bcdi′+a′b′d′e′+a′c′d′e′+a′b′c′e′

A=abc′d′e′i+ab′c′de′i+b′c′d′ei+bcdi+bc′de′i′+acde′i′+a′c′dei+ab′ce′i+ab′cd′+aei′+a′b′d′e′+a′c′d′e′+a′b′c′e′.

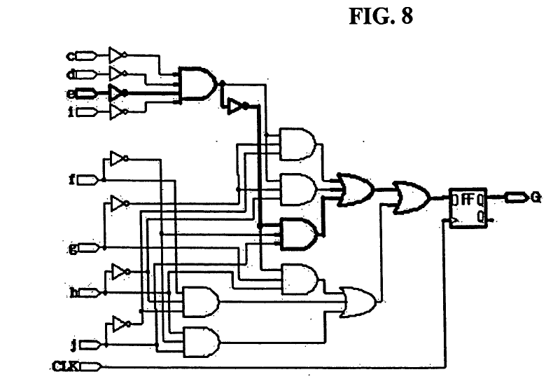

FIG. 8 is a schematic diagram of a logic gate of the critical path process in an 8B/10B decoder according to the present invention. An 8B/10B decoder including logic gates comprises a 5B/6B decoding block for computing 5 bit output data by using 6 bit input data in which the number of ‘0’s and the number of ‘1’s are balanced; a 3B/4B decoding block for computing 3 bit output data by using 4 bit input data in which the number of ‘0’s and the number of ‘1’s are balanced; and a disparity computation block for creating and outputting a disparity in response to outputs and clocks of the 5B/6B decoding block and 3B/4B decoding block.

The 5B/6B decoding block uses a two-group logic combination method. Hence, the critical path process of solving S is achieved through 7 stages reduced from 14 stages and 6 bit input data in which the number of ‘0’s and the number of ‘1’s are balanced are rapidly restored to 5 bit data. The 3B/4B decoding block also uses a two-group logic combination method. Hence, the critical path process of solving j is achieved through 4 stages reduced from 6 stages and 4 bit input data in which the number of ‘0’s and the number of ‘1’s are balanced are rapidly restored to 3 bit data. The disparity computation block is referred to determine whether to make an output signal complemented in computing final output of the 5B/6B decoding block.

Referring to FIG. 8, the two-group logic combination is also used in the 8B/10B decoding block according to the present invention. The process of solving G, the critical path process among 8B/10B decoding process, is achieved through 6 stages of logic gates, which is 4 stages less than the process of solving C, the critical path process among the conventional 8B/10B decoding process.

Thus, an 8B/10B encoder/decoder including logic gates uses a two-group logic combination method with emphasis on speed rather than size. The minimum number of stages for data processing at logic gate level guarantees more stable and fast operation.

The foregoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. An 8B/10B encoder including logic gates comprising:
a 5B/6B encoding block to compute 6 bit output data, in which the number of ‘0’s and the number of ‘1’s are balanced, from 5 bit input data;
a 3B/4B encoding block to compute 4 bit output data, in which the number of ‘0’s and the number of ‘1’s are balanced, from 3 bit input data; and
a disparity computation block to create and output a disparity in response to outputs and clocks of the 5B/6B encoding block and the 3B/4B encoding block.

2. The encoder as defined by claim 1, wherein the 5B/6B encoding block uses a two-group logic combination method.

3. The encoder as defined by claim 1, wherein the 3B/4B encoding block uses a two-group logic combination method.

4. The encoder as defined by claim 1, wherein the disparity computation block checks whether to make an output signal complemented in computing a final output of the 5B/6B encoding block.

5. An 8B/10B decoder including logic gates comprising:
a 5B/6B decoding block to compute 5 bit output data from 6 bit input data in which the number of ‘0’s and the number of ‘1’s are balanced;
a 3B/4B decoding block to compute 3 bit output data from 4 bit input data in which the number of ‘0’s and the number of ‘1’s are balanced; and
a disparity computation block to create and output a disparity in response to outputs and clocks of the 5B/6B decoding block and the 3B/4B decoding block.

6. The decoder as defined by claim 5, wherein the 5B/6B decoding block uses a two-group logic combination method.

7. The decoder as defined by claim 5, wherein the 3B/4B decoding block uses a two-group logic combination method.

8. The decoder as defined by claim 5, wherein the disparity computation block checks whether to make an output signal complemented in computing a final output of the 5B/6B decoding block.
